(19) United States
(12) Patent Application Publication
(10) Pub. No.: US 2010/0000607 A1
(43) Pub. Date: Jan. 7, 2010

(54) All-gaseous deposition of nanocomposite films

(76) Inventors: Luke Hanley, Chicago, IL (US); Igor L. Bolotin, Schaumburg, IL (US); Daniel J. Asunskis, Chicago, IL (US); Amanda T. Wroble, Chicago, IL (US); Adam M. Zachary, Chicago, IL (US)

Correspondence Address: Olson & Cepuritis, LTD., 20 NORTH WACKER DRIVE, 36TH FLOOR, CHICAGO, IL, 60606, US

(21) Appl. No.: 12/310,782

(22) PCT Filed: Sep. 12, 2007
(86) PCT No.: PCT/US2007/019894

§ 371 Date: Mar. 6, 2009

Related U.S. Application Data
(60) Provisional application No. 60/843,996, filed on Sep. 12, 2006.

(51) Int. Cl. H01L 31/0216

(52) U.S. Cl. 136/265; 427/255.23

(57) ABSTRACT

The present invention provides a method of producing a nanocomposite film on a substrate. The method involves co-deposition of gaseous lead salt clusters in a conducting polymer film, such as a conductive polythiophene, on the substrate. The polymer film preferably is simultaneously deposited with the lead salt clusters, e.g., by co-depositing organic monomers and/or oligomers onto the substrate in the presence of gaseous lead salt clusters. Preferred lead salts are PbS, PbTe and PbSe. Devices and articles of manufacture including a nanocomposite film of the invention are also disclosed.

### CROSS-REFERENCE TO RELATED APPLICATION

This application claims the benefit of U.S. Provisional Application for Patent Ser. No. 60/843,996, filed on Sep. 12, 2006, which is incorporated herein by reference.

### STATEMENT OF GOVERNMENT INTEREST

This work was supported by National Science Foundation grant CHE-0241425 and U.S. Department of Defense contract W81XWH-05-2-0093. The government may have an interest in this invention.

### FIELD OF THE INVENTION

The present invention relates to organic-inorganic nanocomposite films for photovoltaic and non-linearly optically absorbing applications.

### BACKGROUND OF THE INVENTION

Physically small structures are being investigated with intense interest. Research in nanotechnology is being conducted, for example, in the fields of electronics, computer science, chemistry and biology. One type of structure being investigated is referred to as a “quantum dot,” which is a particle having a size sufficiently small that the addition or removal of an electron causes the chemical, optical and electrical properties of the structure to be altered in a meaningful manner.

Quantum dots have been studied since the 1980s, for a variety of practical purposes. Often, a practical use of quantum dots requires the quantum dots to be associated with a carrier or other medium, to fix the quantum dots in position and to enhance their desired operational characteristics. A wide variety of different materials have been proposed for use as quantum dots and their carriers. Quantum dots formed of lead salts clusters such as PbS and PbSe have been embedded in a polymer matrix for use in photovoltaics, but only low efficiency photovoltaic devices of this type have been reported. PbS quantum dots have also been proposed for nonlinear optical applications, which include non-linearly optically absorbing. However, both applications employ quantum dot materials prepared from solution.

There are advantages to avoiding the use of colloidal or solution phase methods in forming quantum dots. For example, depending on the material from which they are formed, quantum dots manufactured by liquid deposition may pose health risks to personnel coming into contact with the materials produced or with byproducts of the process. Also, significant quantities of solvents are consumed in the production process, giving rise to environmental concerns.

### SUMMARY OF THE INVENTION

The present invention provides a method of producing a nanocomposite film on a substrate by co-depositing surface polymerizing organic monomers/oligomers and gaseous lead salt clusters on the substrate to form a conducting polymer matrix embedded with the lead salt clusters. The lead salt clusters are preferably selected from the group consisting of lead sulfide (PbS), lead selenide (PbSe), lead telluride (PbTe) and mixed compounds thereof including PbSₓSe₁₋ₓ, PbSₓTe₁₋ₓ and PbSeₓTe₁₋ₓ.

A preferred embodiment comprises simultaneously depositing lead salt clusters and a conducting polymer film so as to embed the lead salt clusters in the conducting polymer film. The present invention provides a nanocomposite film and a method of producing the nanocomposite film by gaseous deposition. The lead salt clusters are formed in a vacuum environment and are trapped in a three-dimensional conducting polymer matrix by the co-deposition process.

The present method provides a nanocomposite film for photovoltaic and non-linearly optically absorbing applications. In particular, a photovoltaic cell or an non-linearly optically absorbing device for blocking laser radiation can include a nanocomposite material as described herein comprising a conducting polymer film and a plurality of lead salt clusters dispersed in the conducting polymer film.

### BRIEF DESCRIPTION OF THE DRAWINGS

FIG. 1 is a schematic representation of an arrangement for producing nanocomposite films;

FIG. 2 is a schematic diagram of an apparatus used for multi-component surface polymerization by ion-assisted deposition (McSPIAD);

FIG. 3 is a UV/Vis spectra of C₂H₄⁺/Ti-phthalocyanine (Ti-Pc) films deposited at various ion to neutral ratios and Ti-Pc only evaporated films;

FIG. 4 shows a scanning electron micrograph of PbS nanocrystals and an inset of an X-ray photoelectron spectrum of the Pb component in this film;

FIG. 5 shows transmission electron micrographs of PbS nanocrystals (at two size scales and histogram of their size distributions;

FIG. 6 shows an arrangement for the electrical characterization of nanocomposite films using an X-ray photoelectron spectrometer;

FIG. 7 shows a survey X-ray photoelectron spectra of a nanocomposite film composed of PbS nanocrystals and titanyl phthalocyanine;

FIG. 8 shows optical absorbance spectra of a nanocomposite film composed of PbS nanocrystals and titanyl phthalocyanine (solid line) and that of titanyl phthalocyanine alone (dotted line);

FIG. 9 shows energy dispersive X-ray spectra of a nanocomposite film composed of PbS nanocrystals and titanyl phthalocyanine; and

FIG. 10 shows transmission electron micrographs (a) lead nanocrystals without organic co-deposition, (b) PbS nanocrystals co-deposited with sexithiophene (inset is expanded view of PbS nanocrystal showing lattice fringes). (c) Particle size distribution and (d) optical absorbance are shown for the composite (b).

### DESCRIPTION OF THE PREFERRED EMBODIMENTS

There are several societal and scientific motivations for studying topics related to photovoltaic production, with the goal of providing new photovoltaics (PVs). These include the high cost of oil, political instability in the major oil-producing regions, global warming resulting from burning fossil fuels, and potential future fuel shortages. These energy issues reemphasize the long-term political and economic need for seeking alternative energy resources [23]. Conversion of solar energy into electricity via photovoltaics is one renewable energy resource that is becoming economically viable [32].

A recent Department of Energy report describes the need for improved PVs that cost less to produce and display higher solar radiation to electrical energy conversion [1]. This report also points out the need for a combinatorial experimental approach for the development of new types of PVs, as their mechanisms of energy conversion are often poorly understood.

It is useful to briefly review the background on Lead Salt-Polymer Nanocomposite PVs. There are many candidates for new types of PVs, but interest is focused herein on quantum dot (QD)-organic nanocomposite materials [24]. A PV must perform several functions to efficiently convert solar radiation to electrical current [25, 26]. First, it must optically absorb a photon, to form an exciton. Second, the exciton must be efficiently ionized and the resultant charges rapidly separated to create current. A variety of QD-polymer nanocomposites have been examined for PVs. C₆₀ [26, 28], carbon nanotubes [29], anatase TiO₂ [30], and CdSe nanorods [31] have been examined for the QD or equivalent phase. A variety of polymers and small organics have also been examined for such PVs including sexithiophene, pentacene, poly(phenylene vinylenes), and metal phthalocyanines [32, 33].

The target PV materials described herein are lead salt quantum dot-conducting polymer nanocomposites [1, 2]. There are several motivations for utilizing lead salt quantum dots (QDs), including lead sulfides (PbS), lead selenides (PbSe), lead tellurides (PbTe), and alloys thereof. The lead salts display strong quantum size effects which ready tuning of their optical absorption with QD diameter [35]. However, perhaps the greatest potential of lead salts involves the possibility of accessing multiple exciton mechanisms for high efficiency, low cost PVs. Traditional PVs create only one exciton per absorbed photon, so even the narrowest bandgap PVs are limited to a theoretical efficiency of ˜32% as photon energies in excess of the bandgap are lost to simple lattice heating. The production and capture of multiple excitons for each absorbed solar photon would boost theoretical PV efficiency above the 32% Shockley-Queisser limit to 50% or more, dramatically improving the economics of solar energy to electric conversion. Multiple exciton generation has been demonstrated for PbSe, PbS, and other QDs using ultrafast laser techniques [36, 37], but this advance has not yet lead to high efficiency PV devices [2, 38].

There are several other potential advantages of PbS QDs in particular. PbS displays a high electron affinity which will enhance charge transfer from the polymer phase. PbS is also inexpensive and highly abundant within U.S. borders, being the most common component of the mineral galena. Finally, PbS is thought to be less toxic than many other nanomaterials, especially those containing cadmium. PV devices composed of PbS or PbSe QDs embedded in a conducting polymer matrix have been produced, but only low efficiency devices of this type have been reported to date [3, 8, 39, 40, 43].

### Formation of Photovoltaic Films

As will be seen herein, the present invention contemplates the formation of conductive films, photovoltaic films and other useful structures, using a variety of methods. Broadly, two techniques are discussed in detail herein. In a first, more preferred class of techniques, gaseous deposition, especially gaseous deposition using one or more evaporation steps is employed. In a second class of techniques, surface polymerization by ion-assisted deposition (SPIAD) is used to polymerize gaseous organic monomers to produce conducting polymer films.

### Background on Gaseous Deposition of Nanomaterials

All the lead salt-polymer nanocomposite PVs devices produced to date have been prepared from the solution phase using colloidal techniques. However, various work has shown that gaseous deposition techniques are quite powerful for producing nanomaterials. Haberland and coworkers demonstrated that intense beams of cluster ions can be prepared by magnetron sputtering of a solid target followed by gaseous condensation to form clusters of sufficient intensity so that they can be deposited as films on surfaces [4]. Haberland sources have been used to prepare novel magnetic nanomaterials by codeposited cluster ions (i.e., Feₙ⁻) with evaporated atoms (i.e., Co) [42, 44]. Decaborane ion deposition has been used for ultrashallow doping of Si wafers [12, 55]. Mass-selected metal ion deposition has been used to prepare metal nanocrystals on oxide supports to probe size-dependent catalytic effects [45, 46].

Gaseous condensation methods are also used to produce both native and organic-functionalized nanoparticles [47, 48]. In fact, one of the largest producers of metal oxide nanoparticles uses gaseous condensation methods (see nanophase.com). Lead salt nanoparticles have been prepared by gaseous condensation of the thermally evaporated salts [49, 50]. Sputtering or sulfur ion implantation have been used to produce PbS QDs in silicate glasses [51, 52]. Finally, a combination of irradiation and gas/solid reactions have been used to produce PbS-polymer nanocomposite fibers from Pb-containing polymer fibers [43].

Ion cluster gaseous deposition techniques and polymer matrix gaseous deposition techniques are combined to form nanocomposite films that exhibit characteristics useful, for example, in photovoltaic and sensor protection devices. According to the present invention, a three-dimensional array of intact ion clusters comprising quantum dots are embedded in a conducting polymer matrix. The ion clusters and the polymer matrix are formed using their own respective gaseous deposition techniques. Varying each gaseous deposition technique, or simultaneously varying both gaseous deposition techniques alters the characteristics of the resulting nanocomposite film. Various examples of gaseous deposition techniques will be discussed herein, beginning with the Gas Phase Deposition of Lead Sulfide Nanocrystal/Titanyl Phthalocyanine Composite Films.

### Gas Phase Deposition of Lead Sulfide Nanocrystal/Titanyl Phthalocyanine Composite Films

Composite materials composed of semiconductor nanocrystals (NCs) dispersed in organic or polymer matrices are considered herein for use in photovoltaics, photodiodes, nonlinear optical devices, and other applications [58]. This interest arises from the possibility of tuning the optoelectronic properties of the nanocomposite by varying the NC size and concentration within the organic matrix [59].

One design of organic photovoltaic employs a nanocomposite film composed of a nanoparticle electron acceptor embedded in an organic or polymeric electron donor [1]. However, the performance of these devices is limited by the ˜10 nm maximum distance over which photogenerated excitons can diffuse before they dissociate into charges (prior to charge collection). This exciton diffusion bottleneck has lead to the development of mixed heterojunction photovoltaic devices, where NCs are closely spaced, multiple donor-acceptor interfaces exist, and efficient charge collection and hoping occurs throughout the entire layer to adjacent electrodes [58].

Lead sulfide (PbS) NC containing thin films are also considered herein for application in photovoltaics and other optoelectronic devices [60-64]. Bulk PbS is a group IV-VI semiconductor with a narrow band gap of 0.41 eV at room temperature [59]. For PbS nanocrystals below 20 nm, strong quantum size effects occur and include a size tunable bandgap. PbS is also an attractive material for the study of quantum confinement effects as its hole Bohr radius is 18 nm [2]. There are several other potential advantages of PbS NCs including their high electron affinity, which will enhance charge transfer from an organic phase.

Lead salt NC-organic photovoltaic devices may be prepared from the solution phase using colloidal techniques [61, 62, 68]. Alternatively, gaseous deposition techniques possess certain advantages for the synthesis of pure NCs, polymer films and their nanocomposites [66-72]. Gaseous deposition is inherently suited to film deposition, is compatible with traditional methods of fabricating semiconductor devices, allows control of disadvantageous oxidation during the deposition process by exclusion of air and solvents, and may reduce the agglomeration of NCs.

Gaseous deposition is used to synthesize a nanocomposite film with <5 nm diameter PbS NCs of narrow size distribution embedded within a titanyl phthalocyanine (TiPc) organic matrix. Different organic matrices can be chosen for specific applications of the nanocomposite [71, 73, 74]. TiPc displays rapid a optical response, easy processability, and large excited state cross section, which allow use of these compounds for various applications, such as organic photovoltaics [75, 76].

Films were deposited using a commercial cluster beam deposition source (Nanogen-50, Mantis Deposition Ltd., Oxfordshire, UK) which combines magnetron DC-sputtering and gas-agglomeration techniques in a fashion similar to that originally developed by Haberland and coworkers [77]. However, the cluster deposition apparatus was modified to input reactive H₂S gas in addition to the noble sputtering/carrier gases typically used in such sources [78].

The mostly negative charged clusters can be accelerated to modulate their interaction with organic component. Soft-landing of the (PbS)n clusters into the soft polymer matrix allow the clusters to maintain their three-dimensional structure upon deposition.

An organic doser and quartz crystal microbalance are employed for thermal evaporation of neutral TiPc and measurement of particle flux rate [79]. The films are deposited on indium tin oxide (ITO) coated glass for optical and structural characterization. Transmission electron microscopy (TEM) is used to measure the size of the NCs in composite films prepared directly on TEM grids.

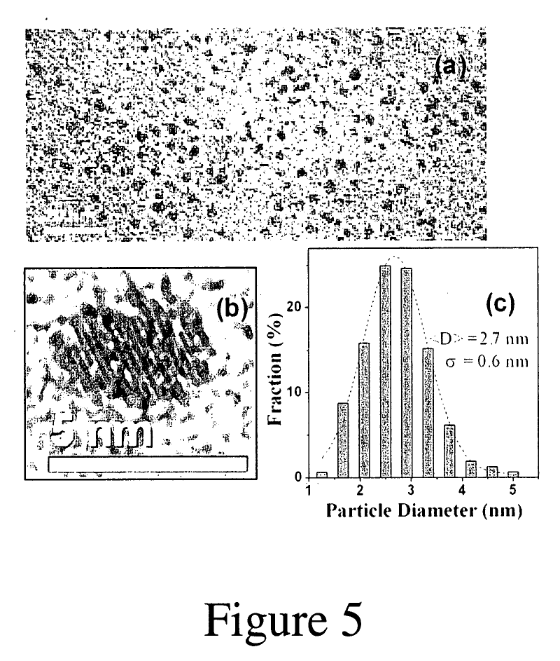

FIGS. 5(a) and 5(b) show a transmission electron micrograph of PbS nanocrystals (NCs) deposited into TiPc and (c) PbS NC size distribution. PbS NCs display a narrow size distribution ranging from 2 to 3 nm and are not agglomerated. FIG. 5(b) displays a higher magnification image of an individual nanocrystal showing PbS lattice fringes.

The size of PbS NCs is an important parameter that determines their bandgap and optical properties. The size of PbS NCs controls not only their linear optical absorbance spectrum [59], but also their extinction coefficients [63]. Both will affect photovoltaic performance. It has also been postulated that narrow NC size distributions and small particle spacings may allow the overlap of NC electronic states and permit multiple exciton generation [80-82]. FIG. 5 shows a TEM image of NC films deposited on a TEM grid at the same conditions as for thick films on ITO coated glass. The PbS NCs appeared homogeneously distributed in the TiPc film. The mean spherical particle size of the NCs was estimated to be 2-3 nm diameter. FIG. 5b shows the TEM image of an individual PbS nanocrystal, clearly revealing the lattice fringes. TEM also showed PbS nanocrystals evenly dispersed throughout the film without agglomeration. The soft-landing of (PbS)n clusters into the soft TiPc organic layer appeared to maintain the three-dimensional structure of the clusters upon deposition and enabled the NCs to retain their sphericity, which is driven by the system minimizing its surface energy to facilitate an energetically more stable nanoparticle. In the absence of the TiPc matrix, (PbS)ₙ clusters aggregated into larger, irregular-sized particles.

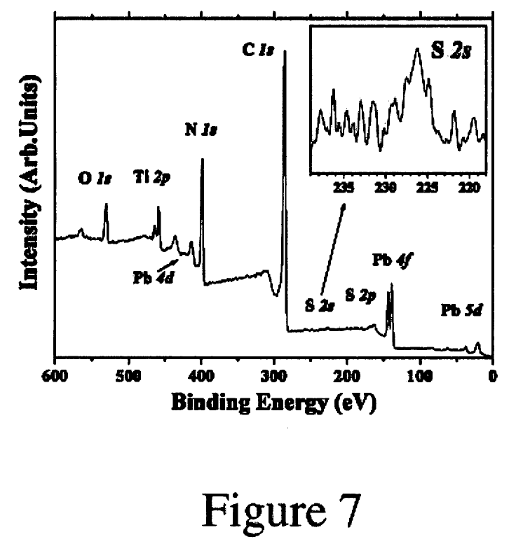

FIG. 7 shows survey X-ray photoelectron spectra (XPS) of the typical PbS—TiPc nanocomposite film showed the S 2p, S 2s, Pb 4f, Pb 4d, Pb 5d, O 1s, C 1s, N 1s and Ti 2p peaks. The S 2s core level (inset) showed no oxidation of the PbS nanocrystals. X-ray photoelectron spectroscopy (XPS) is used to show that PbS is successfully incorporated into the TiPc matrix during co-deposition by determining the surface composition of the nanocomposite films. FIG. 7 presents the XP spectra of a typical PbS—TiPc nanocomposite film. The XPS film content showed the expected elemental content of Pb, Ti, N, C, O, and S where the oxygen present was that originally complexed to the Ti atom in TiPc. With the present invention, no presence of sulfur is detected with H₂S flow and magnetron sputtering is absent, indicating no reaction of H₂S with TiPc. The XPS Pb/S ratio was set to unity by controlling the overall gas flow and setting the ratio of Ar:H₂S at 1:1. Varying flow parameters affected the size of the PbS NCs [83]. The core level C 1s XP spectra showed no change between the TiPc and PbS—TiPc nanocomposite films, indicating the phthalocyanine structure remained intact in the presence of PbS NCs.

PbS NCs can undergo oxidation from air [65,84] which may cause unfavorable changes in their optoelectronic properties. The observed XPS peak position for the deposited film corresponded to unoxidized PbS (FIG. 7). The S 2s region indicated that the majority of the sulfur was sulfide, S²⁻ at 225.5 eV, while oxidized S at 232 eV (i.e., SO₄²⁻) was not observed [84]. The PbS/TiPc nanocomposite films were quite stable to oxidation and did not show any significant changes in the S 2s XP spectra after several days of air exposure.

The formation of PbS NCs was further confirmed by energy dispersive X-ray analysis, where the L_{β}, L_{α}, and M_{α} lines of Pb were readily identified at 12.65, 10.55, and 2.35 keV, respectively. Because the S K_{α} line (2.31 keV) overlapped with the Pb M_{α} line it could not be separately identified. The appearance of Cu and Au signals is attributed to the sample holder and TEM grid, and Ti signal attributed to the TiPc matrix.

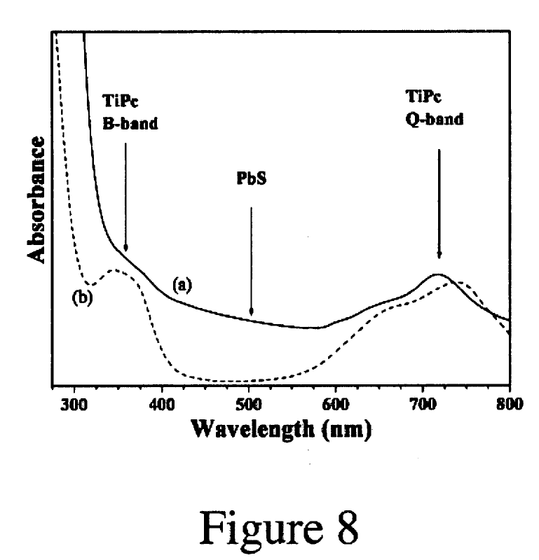

FIGS. 8a and 8b show UV/Vis absorbance spectra of a typical PbS—TiPc nanocomposite film (FIG. 8a) as well as spectra of TiPc pure evaporated film (FIG. 8b) deposited on indium tin oxide (ITO) coated glass. The visual appearance of the deposited nanocomposite film color red-shifted progressively from blue (the color of TiPc only) to pale-yellow as the concentration of PbS increased. Therefore, TiPc films both with and without PbS NCs were characterized with UV/Vis absorbance spectroscopy. FIG. 8 shows a typical reproducible UV/Vis absorbance spectra of PbS—TiPc co-deposited films as well as spectra of TiPc evaporated films (all on ITO coated glass). The TiPc matrix absorbed in the visible spectral range and the observation of a Q-band peak (˜700 nm) and B-band below 400 nm are characteristic features for the TiPc compound [76, 85-87].

However, it is clear that there was a difference between the UV-Vis spectra of pure TiPc and PbS-TiPc nanocomposite films with a strong absorbance for the nanocomposite film appearing in the visible region between 400 and 600 nm. This is attributed to the optical absorbance of the PbS NCs and further confirms their formation within the organic matrix. The spectra of the TiPc matrix also undergoes significant changes after inclusion of the PbS NCs (FIG. 8, curve a). The Q-band for the PbS-containing film was narrower and shifted to a shorter wavelength, possibly resulting from changes to the molecular packing of TiPc in the presence of the PbS NCs.

In summary, the gas phase deposition of nanocomposite TiPc films with embedded <5 nm PbS nanocrystals is employed by the present invention in a cost effective manner. Simple magnetron sputtering of a Pb target in Ar—H₂S atmosphere generates (PbS)ₙ clusters in vacuum which were then trapped in an organic TiPc matrix. TEM analysis found non-agglomerated NCs with mean size of 2.7±0.6 nm. If desired, the size and stoichiometry of the clusters could be tuned by varying source parameters including those affecting sputtering and Ar:H₂S ratio. This universal scheme will also allow deposition of other nanocomposite films composed of any evaporable organic and inorganic nanocrystals that can be produced by sputtering and reaction within the cluster source. For example, Pb NCs have been deposited into TiPc matrices and PbS NCs have been deposited into sexithiophene matrices using these methods. The techniques discussed here are used for the gaseous synthesis of nanocomposite TiPc films with embedded <5 nm PbS nanocrystals. This exemplary deposition method produces (PbS)ₙ clusters by simple magnetron sputtering of Pb target in an Ar—H₂S atmosphere and then trapping them in an organic TiPc matrix. Size classification of PbS clusters found non-agglomerated, ˜2-3 nm diameter nanocrystals of a narrow size distribution.

In one example, a commercial DC-sputtering source (typical power ˜30 W) is used for vaporizing Pb targets and condensing the Pb plasma into clusters (Nanogen-50, Mantis Deposition Ltd, Oxfordshire, UK). The magnetron is operated at Ar and H₂S gas flow rate 15-30 sccm with a 1:1 ratio of Ar:H₂S gas flow injected continuously from an inlet in front of the Pb target. Clusters are formed in the Ar and He carrier gas flow within a water cooled aggregation zone, and ejected through the nozzle and one skimmer (which is differential pumped), then deposited onto substrates in the chamber (at ˜10⁻⁵ torr pressure during deposition). A typical cluster beam current of a few nanoamperes, equivalent to ˜10⁹ clusters/s, was used, but it was not found necessary to determine the neutral to ion fraction of clusters. The doser temperature for the evaporation of neutral TiPc ranges from 570 to 618K. The grids, which consist of carbon-coated film supported by Cu or Au grid, are used as substrates for transmission electron microscopy (TEM) observations. The filling fraction of nanocrystals or mass ratio of TiPc:PbS is monitored by a quartz crystal microbalance. Typical samples displayed a TiPc:PbS mass ratio ranging from 2:1 to 5:1.

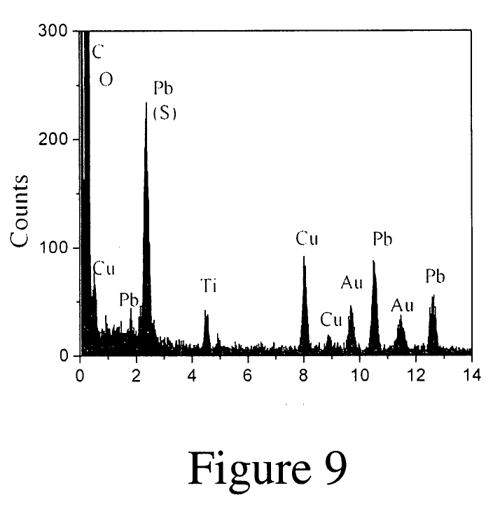

FIG. 9 is a plot showing Energy dispersive X-ray spectra of the typical TiPc-PbS nanocomposite film deposited on carbon film supported on a Cu/Au grid. The appearance of Cu and Au signals was attributed to the TEM grid, and Ti signal was attributed to the TiPc matrix. TEM images and energy dispersive X-ray spectra are obtained by employing a JEOL-3010 microscope operated at an electron beam energy of 300 keV. X-ray photoelectron spectra (XPS) are recorded on samples using a Kratos Axis 165-HS spectrometer operating with monochromatic X-radiation at 150 watts. The spectra are calibrated to the C 1s line from the organic phase at 285 eV. Charge neutralization was carried out on all samples using a low energy electron flood gun to eliminate sample charging during analysis.

### Lead Sulfide Nanocrystal-Polymer Composites for Optoelectronic Applications

Nanocomposite films are prepared in which lead sulfide (PbS) nanocrystals are contained in an organic matrix. These films are prepared by gaseous deposition of nanocrystals into the organic phase. The nanocrystals in the composites are free from surfactant capping layers that otherwise would add an interfacial region between the nanocrystal and the organic matrix. The gaseous deposition technique has several advantages over wet chemical synthesis in that it allows direct control over nanocrystal size and density, improved flexibility in the choice of organic phase, and is compatible with lithographic methods.

Lead sulfide (PbS) is a group IV-VI semiconductor with a bulk band gap of 0.41 eV. PbS nanocrystals have a size-tunable band gap, from the visible into the near-infrared region, and have potential as photovoltaics, photodiodes, and nonlinear optical devices [88-94]. PbS is one of several types of semiconductor nanocrystals which are considered herein for high efficiency photovoltaics via a multiple exciton generation mechanism [95].

PbS nanocrystals are typically synthesized using colloidal methods in which surfactant molecules in solution act as size limiters in the growth of the nanocrystals [89]. These surfactant molecules cap the surface of the nanocrystals and become an additional layer or interfacial region when the nanocrystals are dispersed in an organic matrix.

The surfactant capping groups on nanocrystals can greatly affect the properties of the composite. Methods are therefore required in which the nanocrystals can be grown within or deposited into an organic phase without this capping layer. Composite materials of PbS nanocrystals in polymers were synthesized by colloidal methods where the nanocrystals were grown directly in the presence of a polymer which acted as the size-limiting reagent [94].

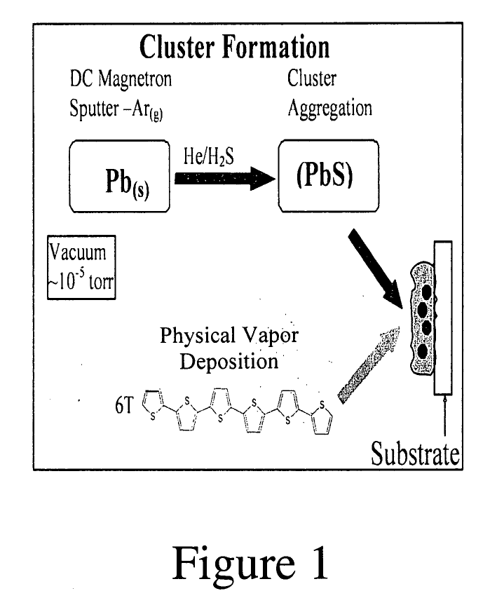

FIG. 1 shows an alternate method: gaseous deposition which creates semiconductor nanocrystals and co-deposits them within an organic matrix. PbS nanocrystal-polymer composite films are prepared by both the established colloidal method [94] and this new gaseous deposition method. Both methods prepared composites that were free of surfactants capping the PbS nanocrystals. As can be seen in FIG. 1, a schematic diagram is shown for the co-deposition of PbS nanocrystals with an organic phase via gaseous deposition using a Haberland source [96] for cluster formation and physical vapor deposition of the organic phase.

### Gaseous Deposition of PbS-Sexithiophene Composite Films

The gaseous deposition of nanocrystal-organic oligomer composite films is designed to produce similar films as those prepared by the colloidal method. The gaseous deposition method also produces nanocrystals free of surfactant groups, similar to the colloidal techniques. A commercial Haberland-type cluster source (Nanogen-50, Mantis Deposition Ltd., Oxfordshire, UK) [96] is employed for PbS gaseous cluster formation. This source produces gaseous lead species by magnetron sputtering of a metallic lead target. The lead vapor is reacted with hydrogen sulfide gas to form lead sulfide vapor which travels through a water-cooled aggregation zone under a flow of helium gas, leading to cluster condensation in vacuum. The clusters exit the source to be co-deposited with an organic oligomer emitted from a heated organic doser. The deposition rates of the neutral organic layer and nanocrystals are monitored in situ by quartz crystal microbalance and UV-visible absorption.

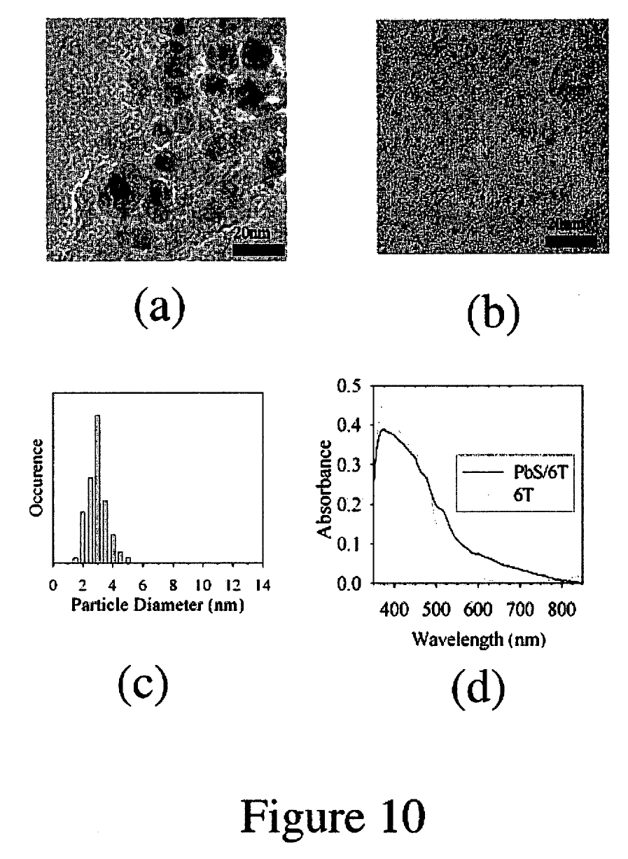

FIGS. 10a-10d show a gaseous deposition of nanocrystals, with a TEM image of the deposition of (FIG. 10a) lead nanocrystals without organic co-deposition, (FIG. 10b) PbS nanocrystals co-deposited with sexithiophene (inset is expanded view of PbS nanocrystal showing lattice fringes, see FIG. 10c). Particle size distribution and (FIG. 10d) UV-visible absorption are shown for the composite (FIG. 10b). A TEM image of lead nanoparticles deposited alone is shown in FIG. 10a. This TEM image indicates clumping and aggregation of the lead particles occur in the absence of a co-deposited organic. However, when nanocrystals of Pb are deposited with an organic matrix, spherical nanocrystals are formed. PbS clusters co-deposited with a sexithiophene (6T) organic oligomer lead to the film examined by TEM in FIG. 10b: The spherical nanocrystals are uniformly dispersed in the composite and do not show the clumping seen in FIG. 10a. The inset of FIG. 10b shows the lattice fringes of the PbS particle, indicating crystallinity.

The mean particles size of the nanocrystals in the 6T was found to be ˜3 nm, with a smaller size distribution shown in FIG. 10c than was observed for the colloidal synthesis with MEH-PPV. The UV-visible absorption spectrum for the PbS/6T composite, FIG. 10d, showed a similar increase in broadband absorption to what was seen in the synthesized PbS/MEH-PPV composite.

Despite the similarity of the composite films prepared from the two methods, the gaseous deposition has several distinct advantages over the wet chemical synthesis. One advantage is the flexibility in selection of the organic phase. The gaseous deposition allows any evaporable material to be used while solubility in the solvent and nanocrystal size distribution are interrelated in the colloidal method. Thus, the desire for a specific particle size can limit the potential choices for the polymer in the colloidal method. By contrast, the size of the clusters produced in gaseous deposition could be tuned independently of the organic phase, for example by increasing or decreasing the gas flow rate or the length of the aggregation zone [96].

The gaseous deposition technique also has the ability to directly tune the nanocrystal density in the composite film, without affecting the nanoparticle size, by adjusting the rate of organic dosing. Tuning particle density in the colloidal method is accomplished by varying the nanocrystal reactant to polymer ratio, but this also affects the particle size distribution.

Finally, the gaseous deposition technique could directly grow thin films of the nanocomposite in a fashion compatible with the lithographic techniques commonly used by the microelectronics industry. By contrast, the colloidal method requires additional steps to remove excess solvents prior to thin film casting.

### Polymer Matrix Gaseous Deposition

In one example of the present invention, a nanocomposite film is produced having characteristics useful as a photovoltaic device. The present invention embeds a three-dimensional array of ion clusters or quantum dots having a substantial three-dimensional structure in a conductive polymer matrix suitable for use in a photovoltaic device. In one example, the quantum dots are formed of PbS or PbSe.

Quantum dots must be embedded into a matrix for practical use in a photovoltaic device. One example of a matrix employed with the present invention is a conducting polymer film which generates multiple exciton activity by controlling the quantum dot spacing and surface chemistry [2, 3]. The matrix, or polymer phase, can also behave as a hole conductor, optical absorber and electron donor. Various conducting polymer films are provided, based upon precursors that include, for example, sexithiophene, pentacene, poly(phenylene vinylenes) and metal phthalocyanines.

### Alternative Film Formation Methods

Various methods can be used to deposit conducting polymers or oligomers on surfaces. These methods include simple evaporation of oligomers, photopolymerization, electron beam polymerization, plasma polymerization or laser ablation of polymers. Other applications are well-known to those skilled in the art. In carrying out the present invention, the preferred method of film formation is to utilize a gas phase deposition process, especially one that utilizes evaporation as a concluding step.

According to a less preferred method, films are formed using surface polymerization by ion-assisted deposition (SPIAD) is used to polymerize gaseous organic monomers to produce conducting polymer films. However, as pointed out above, many other ways of making organic films such as the more preferred gaseous deposition methods described above could be employed, as well. For example, another all-gaseous method of producing nanocomposite films has 5 recently been described using evaporative techniques [56]. A paper describing this latter method, along with German Patent No. DE 10316379 A1 (Nov. 4, 2004) by F. Faupel et al. are discussed in a Vacuum Technology Coating article [57].

SPIAD has been previously used to grow polythiophene films by the simultaneous deposition of <200 eV thiophene ions and evaporated terthiophene neutrals [16]. This work showed that the extent of polymerization and the optical properties of the polythiophene film are tuned by control of ion energy and ion to neutral ratio [17, 21]. Film thickness is trivially controlled down to the subnanometer scale by varying the overall fluence of ions and neutrals.

According to one aspect of the present invention, it has been discovered that the essentially combinatorial approach of SPIAD is extended by use of new ions such as Ar⁺ or C₂Hₓ⁺ and/or neutral species such as terphenyl, poly(phenylene vinylenes), or metal phthalocyanines. Furthermore, a second doser is installed for the deposition of mixed polymer films to enhance, for example, both hole and electron conduction [2]. Arrays of nanocomposites are prepared on single substrates by tuning these various experimental parameters, and then screening the resulting products for photovoltaic properties using surface photovoltage spectroscopy with a solar simulating lamp and a Kelvin probe [10]. Those candidate films displaying the strongest surface photovoltage response in the solar spectrum will be further characterized by photoemission and electron microscopy.

According to another aspect of the present invention, it is important that the conducting polymer matrix be compatible with the sputtering processes used to form the ionic clusters, in both a chemical as well as a physical sense. For example, it is important that the conducting polymer matrix provide a soft landing for the sputtered ionic clusters, so as to preserve their three-dimensional cluster structure.

Further details concerning the formation of the conducting polymer matrix and a description of exemplary materials are found in U.S. Patent Application Publication No. US2004/0247796 dated Dec. 9, 2004, the disclosure of which is incorporated by reference as if fully set forth herein. Work has progressed and films have now been produced with materials in addition to polythiophene.

For example, the organic ion and neutral oligomers of the monomers include, but are not limited to, thiophene, dithienothiophene, ethylenedioxythiophene, terphenyl, sexiphenyl, pentacene, diphenyl perylene, aniline, phenylene, phenylene vinylene, pyridine, a phthalocyanine, a porphyrin, bithiazole, oligomers, and derivatives of all of the above, and mixtures thereof.

The substrate for the conducting polymer film can be, for example, a metal (e.g., gold), a semiconductor, a ceramic, a plastic, a polymer, a self-assembled monolayer, or a nanotube. Other substrates that are known to persons skilled in the art, and that are stable in a vacuum, also can be used.

The present method has been used to prepare polythiophene and phthalocyanine films. However, the present method is not limited to polythiophene. The present SPIAD method can be used in the preparation of essentially any organic conducting polymer, both homopolymers and copolymers, for example, polyterphenyl.

Examples of organic ions useful in the preparation of the organic phase include, but are not limited, to H⁺, H₂S⁺, SO₃⁺, C₂Hₓ⁺, C₄H₄S⁺, C₆H₆⁺, C₆H₇N⁺, C₅H₅N⁺, C₄H₄O⁺, and other small organic ion species as well as derivatives thereof, and mixtures thereof.

Other specific oligomers for producing the organic phase include, but are not limited to, terthiophene, sexithiophene, ethylenedioxythiophene, terphenyl, quaterphenyl, sexiphenyl, poly(phenylene vinylenes), porphyrins, phthalocyanines, pentacene, diphenyl perylene, derivatives thereof, and mixtures thereof.

As mentioned, the present invention can be employed to provide significant advances in the field of sensor protection and non-linearly optically absorbing devices. In these types of applications, it is important that the polymer matrix be sufficiently clear. At least some of the same materials described above can also be applied as optical limiters.

### Nanocomposite Film Preparation by Multicomponent SPIAD (McSPIAD)

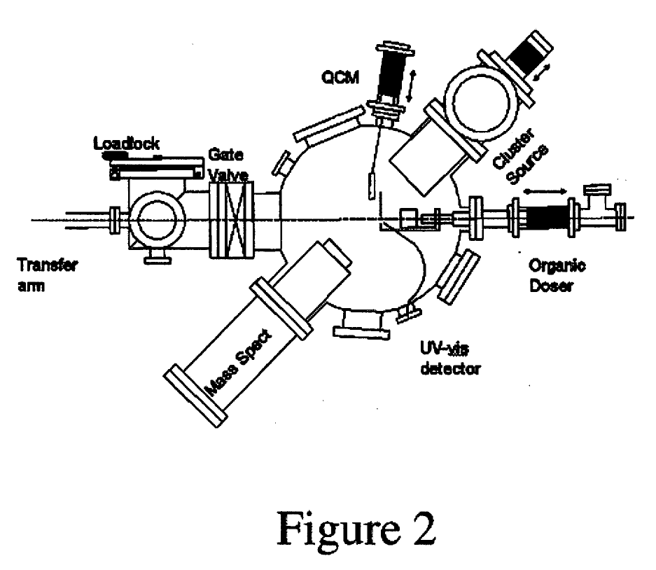

Lead salt-polymer nanocomposite thin films are deposited using a gaseous deposition method that has evolved from the SPIAD technique, referred to herein as multicomponent surface polymerization by ion-assisted deposition (McSPIAD). The McSPIAD procedure and apparatus are depicted schematically in FIGS. 1 and 2, respectively. In FIG. 1, a schematic diagram of multicomponent surface polymerization by an ion-assisted deposition (McSPIAD) procedure is shown. PbS is used to denote a typical QD component while thiophene ions and terthiophene are used to signify a typical polymer component. FIG. 2 is a schematic diagram of an apparatus for performing the McSPIAD procedure. Note that the Kaufman ion gun is actually located above the organic doser, angled downwards onto the sample.

The McSPIAD apparatus can be used to embed 1 to 10 nm diameter PbS or PbSe QDs into embedded conducting polymer films up to a few microns thick. The films are prepared by simultaneous gaseous deposition of PbS (or PbSe) cluster ions and surface polymerization of gaseous organic monomers by ion-assisted deposition. PbS cluster ions are prepared by magnetron sputtering of a solid target followed by gaseous condensation to form clusters in a Haberland source [4]. Various work has shown that PbS and PbSe can be magnetron sputtered [54]. A commercial cluster source (Mantis Deposition Ltd., Oxfordshire, UK) can be used for deposition. The Mantis source produces clusters in the 1-10 nm size range which can be size-tuned by adjustment of the gas flow and magnetron position. Furthermore, the mostly negatively charged clusters can be accelerated to modulate their interaction with the conducting polymer component. However, soft-landing of cluster ions into the soft polymer matrix will allow the clusters to maintain their three-dimensional structure upon deposition.

The polymer phase of the nanocomposite films is prepared by SPIAD, which polymerizes gaseous organic monomers to produce conducting polymer films. SPIAD has been previously used to grow polythiophene films by the simultaneous deposition of <200 eV thiophene ions and evaporated terthiophene neutrals [13, 15]. This work showed that the extent of polymerization and the optical properties of the polythiophene film can be tuned by control of ion energy and ion to neutral ratio [16, 17]. Film thickness can be trivially controlled down to the subnanometer scale by varying the overall fluence of ions and neutrals.

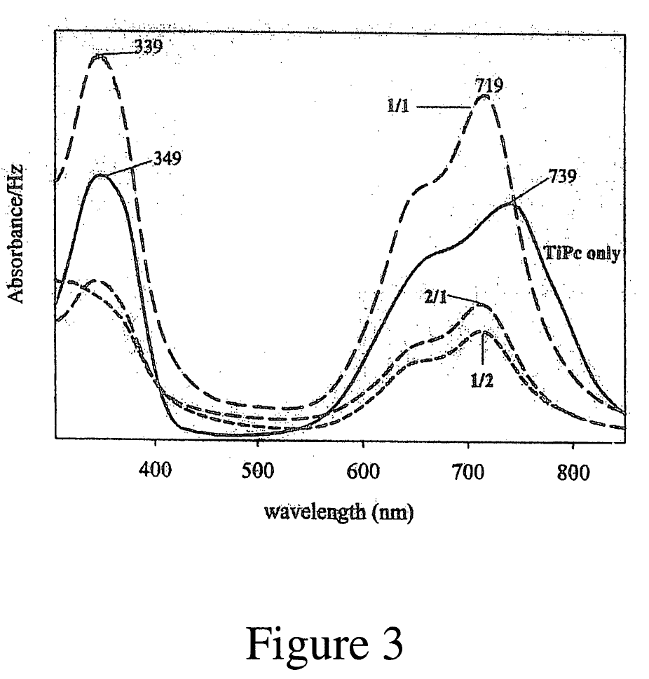

FIG. 3 shows UV/Vis absorbance of 50 eV C₂Hₓ⁺/Ti-Pc SPIAD films deposited at ion to neutral ratios of 1/1, 1/2, 2/1, and Ti-phthalocyanine (Ti-Pc) only evaporated films grown on ITO coated glass. All films are normalized by the quartz crystal microbalance (QCM) frequency change, which is proportional to film thickness. Integer numbers on peaks correspond to maximum wavelength in nm.

Recent work has shown that the essentially combinatorial approach of SPIAD can be extended by use of new ions such as Ar+ or C₂Hₓ⁺ and/or neutral species such as terphenyl [21] or metal phthalocyanines, both of which have been used in organic PVs. For example, the UV/Vis absorption of Ti-phthalocyanine films can be shifted by SPIAD using various acetylene (C₂Hₓ⁺) ion/neutral ratios, as shown in FIG. 3. Combinatorial section of optical properties is achieved in SPIAD by tuning either ion/neutral ratios or ion energies [17].

Various chemical and morphological analyses have been applied to these films. Prior work has demonstrated that x-ray photoelectron spectroscopy [15], scanning electron microscopy [19], x-ray diffraction [19], mass spectrometry [16, 17], and the quartz crystal microbalance [17] can be used to characterize SPIAD film chemistry, morphology, crystallinity, polymerization, and thickness. An x-ray/ultraviolet photoelectron spectrometer is employed herein.

Previous work has shown that changes in the highest occupied electronic states of SPIAD vs. evaporated organic films can be determined by ultraviolet photoelectron spectroscopy, a method well-developed for probing organic film valence bands [53]. Previous work combined ultraviolet photoelectron spectroscopy with near edge x-ray photoelectron spectroscopy to show that the bandgap of SPIAD films is reduced compared to their evaporated counterparts [21]. However, electron energy loss is a better method to probe organic film bandgaps.

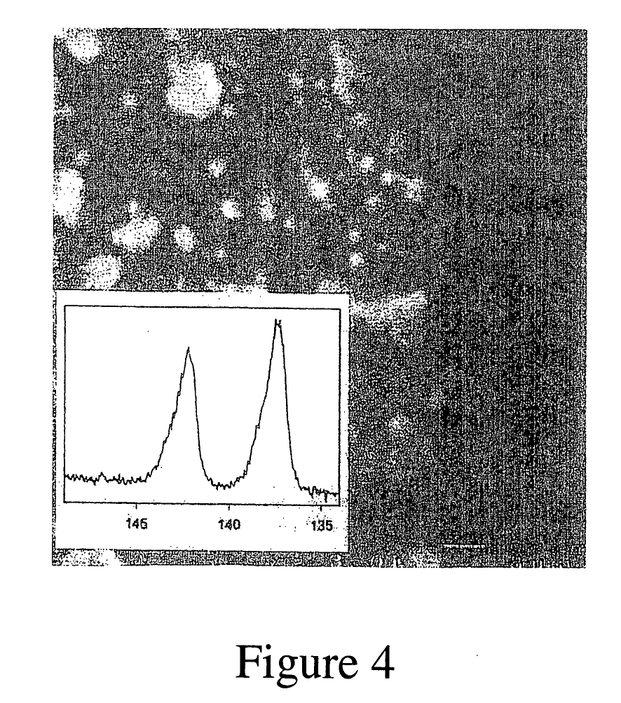

The engineering of interfaces using ion beam deposition to raise the work function of a substrate will now be considered, with initial emphasis on blocking exciton transport. The Haberland cluster gun has been recently used to deposit PbS cluster ions on solid surfaces and the films measured by scanning electron microscopy. The PbS clusters appear ˜20-50 nm in diameter on image, but are likely agglomerated following deposition. Agglomeration can be avoided by simultaneous deposition into soft polymer films. The film content is verified by x-ray photoelectron spectroscopy of the Pb (see FIG. 4) and S components (data not shown). FIG. 4 shows a scanning electron micrograph of PbS cluster ions deposited on a substrate. The inset depicts characteristic Pb_{4f} spin-orbit split peak from x-ray photoelectron spectroscopy of the PbS film appearing between 135-145 eV binding energies.

The next step in PbS-polymer nanocomposite film deposition involves simultaneously depositing PbS cluster ions and organic films by SPIAD. Arrays of nanocomposites are prepared on single substrates by tuning the various McSPIAD experimental parameters. The arrays are screened for photovoltaic properties using surface photovoltage spectroscopy, as further described below.

Finally, the optimal films are examined by the aforementioned characterization methods as well as methods utilizing surface photovoltage techniques.

Further, U. S. Patent Application Publication 2006/0243959, published Nov. 2, 2006 (the disclosure of which is herein incorporated in its entirety) may be used to configure a photovoltaic cell to take full advantage of the techniques considered herein. In one example of photovoltaic cell according to the present invention, a nanocomposite film is prepared by any of the methods herein, so as to be deposited onto a transparent conductive electrode such as indium tin oxide coated glass then coated with a ˜10 nm thick aluminum overlayer. When connected to an external circuit and exposed to ambient solar radiation (AM1.5) leading to a light to electricity external power conversion efficiency in excess of 10%, as determined by the standards and methods set forth by the U.S. National Renewable Energy Laboratory.

### Quantum Dots Formed by Gaseous Deposition

Several gaseous deposition techniques have been discussed above as being preferred for film preparation. The alternative methods of film formation are also desirable from a technical standpoint, but are less favored because of the their increased cost. The following discussion returns to gaseous deposition techniques, with a view toward the formation of quantum dots.

### Ion Cluster Gaseous Deposition

Although quantum dots of various materials have been proposed for use in photovoltaics and other applications, and are employed in the present invention, development of the present invention has focused on three-dimensional structures of lead salts. According to one aspect of the present invention, quantum dots of PbS and PbSe are of interest for several reasons. For example, exciton generation has been observed for PbS and PbSe quantum dots, and both types of nanostructures display strong quantum size effects. Furthermore, PbS has a high electron affinity that enhances charge separation in nanocomposite structures, such as those most preferred in practicing the present invention. As a further advantage, PbS occurs naturally as galena, an inexpensive and abundant mineral with significant deposits throughout the United States.

In one embodiment, PbS cluster ions are preferably prepared by magnetron sputtering of a solid target followed by gaseous condensation to form clusters in a Haberland source [4]. As is known, PbS and PbSe are magnetron sputtered [5]. A commercial cluster source (Mantis Deposition Ltd., Oxfordshire, UK) is used for deposition. This source employs a He/Ar gas flow to condense atomic and diatomic species sputtered from the target into cluster ions. The Mantis source produces intact clusters in a size range of about 1 to about 10 nm which are size-tuned by adjustment of the gas flow and magnetron position. An alternate strategy for producing PbS cluster ions is to magnetron sputter a pure Pb target while introducing a small concentration of H₂S gas into the He/Ar flow of the source. The mostly negatively charged clusters are accelerated to modulate their interaction with the conducting polymer component. According to one aspect of the present invention, a soft landing is provided for the ionic clusters, during their deposition. In one example, a soft-landing of cluster ions is provided by a soft polymer matrix that allows the clusters to maintain their three-dimensional structure upon deposition, as opposed to the relatively small atomic and diatomic species predominantly formed by magnetron sputtering. It is important that the three-dimensional structure of the clusters be preserved for maximum effectiveness and reproducability.

The present invention can also employ a wide variety of semiconductor materials other than lead salts. For example, quantum dots suitable for use in the present invention are prepared from virtually any solid material that can be sputtered onto a soft landing medium (e.g., metals, metal oxides, metal sulfides, metal nitrides and various semiconductors). Several examples include cadmium sulfide, cadmium selenide, and gallium arsenide.

### Nanocomposite Film Preparation

PbS or PbSe quantum dots having diameters between about 1 to about 10 nm are embedded into conducting polymer films up to a few microns thick. The films are preferably prepared by simultaneous gaseous deposition of PbS (or PbSe) cluster ions and surface polymerization of gaseous organic monomers by ion-assisted deposition, as shown schematically in FIG. 1 (using thiophene ions and terthiophene to signify a typical polymer component).

The gaseous deposition method employed in the present invention allows combinatorial tuning of film properties by selection of the SPIAD ion/neutral ratio, the organic ion or neutral structure, the organic or cluster ion kinetic energy, the cluster source deposition conditions which select cluster size, or the cluster to conducting polymer film deposition rate. Quantum dot aggregation in the film is minimized by Coulombic repulsion of the deposited clusters and ions. Variation of the elemental content of the quantum dots is also possible and should change the macroscopic properties of the film. PbSₓSe₁₋ₓ quantum dots of various x values are generated by sputtering a PbSe target in the presence of various pressures of hydrogen sulfide gas [5]. The mA currents of the ion and cluster source allow deposition of ˜1 μm thick films in tens of minutes, indicating that scaling to roll-to-roll manufacturing is feasible [17, 19].

Control of the well-known deposition parameters, such as those described above, are advantageously employed to improve photovoltaic efficiency by several pathways. For example, film optical absorption is matched to the solar spectrum in the near infrared region by tuning the quantum dot size distribution and to the ultraviolet/visible (UV/Vis) region by tuning the conducting polymer film properties, a feature useful when fabricating optical protection or other non-linearly optically absorbing devices of the type contemplated by the present invention. Further, multiple exciton generation events are enhanced by controlling the spacing of individual lead salt quantum dots.

In addition, multiple exciton generation is enhanced and charge separation is increased by tuning the surface chemistry at the quantum dot surface through selection of the polymer phase or the organic or cluster ion energy, in a previously described manner [12, 13].

Also, hole transport is increased by increasing the concentration of free protons within the polymer film [19] The charge separation is increased by increasing quantum dot-polymer phase bonding and additional advantages are attained by varying the elemental content, morphology [21] or other properties to improve the optoelectronic properties of the nanocomposite film.

There are several other advantages of the present all-gaseous deposition method. For one, the process employed in practicing the present invention allows control of disadvantageous oxidation during the deposition process by excluding air and solvents. Unfortunately, PbS quantum dots are known to undergo oxidation from air and/or water with unknown changes occurring in their optoelectronic properties [22]. The all-gaseous methods preferably employed in the present invention are also compatible with other gaseous deposition processes used in the production of photovoltaic devices. Examples include known evaporation techniques employing an aluminum cathode or techniques of physically enhanced chemical vapor deposition of an oxidation barrier layer [9].

In addition, the all-gaseous deposition procedures described herein are environmentally sound and sustainable for several reasons. These procedures use little or no solvents, leading to much less chemical waste compared with solution-based methods. Also, quantum dots prepared from solution may cause adverse health effects. The present gaseous deposition procedures produce deposits of quantum dots in a vacuum environment, and then trap the quantum dots in a conducting polymer matrix. This method minimizes the release of these potential hazardous quantum dots to the ambient environment. Known techniques may be readily employed to trap any nanoparticulate dust upon opening the chamber by solvent rinsing the chamber prior to handling.

### Example

As discussed above, in one example, a nanocomposite film for use as a photovoltaic device is produced having PbS or PbSe quantum dots having diameters between about 1 to about 10 nm embedded into a conducting polymer film of C₂Hₓ⁺ and titanyl phthalocyanine (TiPc) up to a few microns thick. The film is produced using conventional Surface Polymerization by Ion-Assisted Deposition (SPIAD) techniques to polymerize a TiPc layer.

Preparation of the film also requires gaseous PbS (or PbSe) cluster ion deposition that occurs simultaneously with the TiPc layer polymerization described above. The deposition of the clusters is carried out in a known manner so as to preserve the ionic three-dimensional structure. Further, the initial layer of conducting polymer provides a soft landing for the three-dimensional ionic structures, and continuous co-deposition of the ion clusters and the conducting polymer serves to preserve the three-dimensional structure of subsequent ion depositions. It is generally preferred that deposition of the cluster ions is limited to a target size slightly smaller than that of the conducting polymer deposition.

Finally, the resulting three-dimensional array of three-dimensional ionic structures and the conducting polymer medium is encased by a final layer of conducting polymer. As a result, the ionic structures are completely embedded within the conducting polymer, such that their three-dimensional spacing is preserved, while the operational characteristics of the ionic structures as quantum dots is enhanced by the conducting polymer. Deposition of the ionic structures is carried out in a vacuum environment, as is the deposition of the conducting polymer, thereby reducing or eliminating health risks associated with production of the nanocomposite film.

### Characterization Methods

Those skilled in the art will readily appreciate that a wide variety of known, commercially developed evaluation techniques are available to evaluate nanocomposite products made according to the present invention. For example, arrays of nanocomposite films are prepared by gaseous deposition, then screened in vacuum using surface photovoltage spectroscopy with a solar simulating lamp and a Kelvin probe [10]. The films displaying the strongest surface photovoltage response in the solar spectrum can be further characterized by photoemission, x-ray scattering and electron microscopy.

Photoemission studies can be performed [12, 13, 15, 16]. For example, a combined monochromatic x-ray and ultraviolet photoelectron spectrometer equipped with a low energy electron flood gun for charge neutralization or electron energy loss spectroscopy is used to determine film band gaps. Films prepared in the deposition apparatus are vacuum transferred into the adjacent photoemission apparatus for surface characterization of elemental content and functional group determination [12, 13] using x-ray excitation.

Ultraviolet photoemission determines the underlying substrate work function, ionization potentials of the nanocomposite film, the barrier to hole injection from the substrate to the film, the surface density of occupied states including the highest occupied molecular orbital and the Fermi level/vacuum level offset (S). It is helpful to carry out photoemission techniques on PbS-polymer nanocomposites prepared by colloidal techniques [22]. A type of element specific surface photovoltage spectroscopy can be performed here using the x-ray photoelectron spectrometer, a monochromated light source and the low energy electron flood gun [10]. Photoemission techniques have recently been developed that allow non-contact measurement of electrical properties of thin films, such as current vs. voltage curves [10, 27, 34, 41].

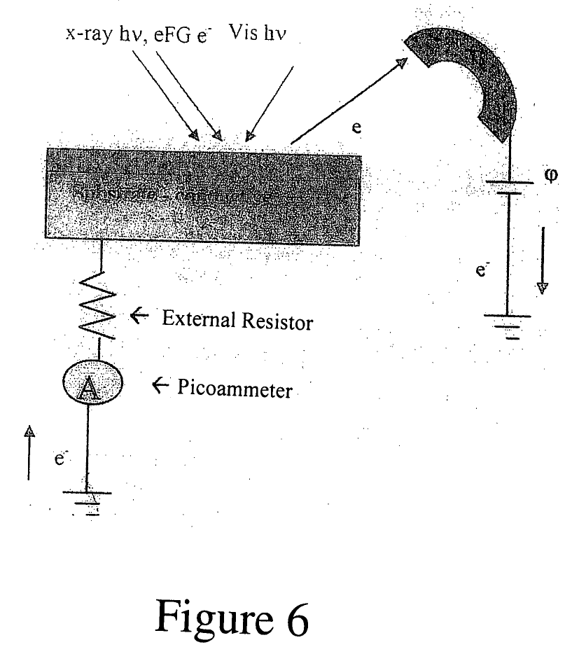

With reference to FIG. 6, morphological characterization of the nanocomposite films is also accomplished using scanning [21] and transmission [22] electron microscopy. X-ray surface scattering: diffraction [19, 21] reflectivity [14] and standing wave fluorescence [20] determine the quantum dot and polymer phase crystallinity, the quantum dot distribution in the film normal to the substrate, and the roughness of both air and buried interfaces. UV/Vis optical absorption and photoluminescence of the nanocomposite films is also performed [17, 19]. Further details concerning the method of characterizing the photovoltaics that is depicted in FIG. 6 may be found in U.S. Published Patent Application 20060103395 A1 by Hagai Cohen and Igor Lubomirsky, published May 16, 2006, the disclosure of which is herein incorporated by reference in its entirety.

### Conclusion

As described above, an all-gaseous deposition method is disclosed for the production of a nanocomposite film, such as lead salt-organic nanocomposites for various applications such as solar to electric conversion. In another example, the present invention is employed to provide sensor protection or other types of visual limiting devices, in the form of visors or lenses, to protect a wearer from harmful radiation. Such protection is essential for aircraft personnel engaged in civilian as well as military activities, as well as scientists conducting studies in a radiation producing environment.

In one example of an optical device according to the present invention, a lens or a coating on a lens is formed of a nanocomposite material, comprising a conducting polymer film and a plurality of lead salt clusters dispersed in the conducting polymer film. In one application, the optical device attenuates pulsed laser radiation of wavelengths ranging from about 400 to about 900 nm incident on the device surface such that the radiation transmitted by the device does not exceed a laser power density of about 15 microJoules/cm² per pulse.

Nanocomposites according to the present invention, when adapted for ultrahigh efficiency photovoltaics, may exceed the Shockley-Queisser limit by multiple exciton generation [1, 2]. In practice, arrays of nanocomposite films are combinatorially screened by surface photovoltage measurements, and the candidate film displaying the largest photovoltages is further characterized by photoemission, x-ray scatterings and electron microscopy.

The all-gaseous deposition according to the present invention provides substantial economic advantages, since it is scalable to a manufacturing process. Further, the all-gaseous deposition is also helpful in guiding colloidal preparation of analogous nanocomposites. Further, as described, the present invention provides previously unattainable advantages in producing photovoltaic devices as well as devices used for sensor protection and other types of nonlinear optical devices.

### Publications

The following publications, cited throughout this application, are incorporated herein by reference in their entirety.

| | |
|---|---|
| [1] | N. S. Lewis et al., Basic Energy Needs for Solar Energy |
| | Utilization: Report on the Basic Energy Sciences Workshop |
| | on Solar Energy Utilization, Washington, D.C., DOE (2005). |
| [2] | A. Nozik, Inorg. Chem. 44, 6893 (2005). |
| [3] | S. Zhang, P. W. Cyr:, S. A. McDonald, G. Konstantatos, |
| | E. H. Sargent, Appl. Phys. Lett. 87, 233101 (2005). |
| [4] | H. Haberland, M. Karrais, M. Mall, Y. Thurner, J. Vac. Sci. |
| | Technol. A 10, 3266 (1992). |
| [5] | G. H. Mihailescu, G. H. Borodi, R. M. Candea, J. Mater. Sci. |
| | Lett. 13, 1675 (1994). |
| [6] | A. A. R. Watt, D. Blake, J. H. Warner, E. A. Thomsen, E. L. |
| | Tavenner, H. Rubinsztein-Dunlop, P. Meredith, J. Phys. D: |
| | Appl. Phys. 38, 2006 (2005). |
| [7] | D. Qi, M. Fischbein, M. Drndic, S. Selmic, Appl. Phys. |
| | Lett. 86, 093103 (2005). |
| [8] | X. Jiang, S. B. Lee, L B. Altfeder, A. A. Zakhidov, R. D. |
| | Schaller, J. M. Pietryga, V. I. Klirnov, SPIE 5938, 57 (2005). |
| [9] | G. Dennler, C. Lungenschmied, H. Neugebauer, N. S. |
| | Sariciftci, A. Labouret, J. Mater. Res. 20, 3224 (2005). |
| [10] | S. K. Sarkar, H. Cohen, G. Hodes, J. Phys. Chem. B 109, |
| | 182 (2005). |
| [11] | M. B J. Wijesundara, L. Hanley, B. Ni & S. B. Sinnott, |
| | “Effects of unique ion chemistry on thin-film, growth by |
| | plasma-surface interactions,” Proc. Nat. Acad. Sci. U.S.A. |
| | 97 (2000) 23. |
| [12] | L. Hanley & S. B. Sinnott, “The growth and modification of |
| | materials via ion-surface processing,” Surf. Sci. 500 (2002) |
| | 500 (special volume on surface science in the new |
| | millenium). |
| [13] | M. Tepavcevic, Y. Choi & L. Hanley, “Surface |
| | polymerization by ion-assisted deposition for polythiophene |
| | film growth,” J. Am. Chem. Soc. 125 (2003) 2396. |
| [14] | F. A. Akin, M. L. Schlossman, S. B. Sinnott, & L. Hanley, |
| | “Nanostructure of fluorocarbon films deposited on |
| | polystyrene from hyperthermal C₃F₅⁺ ions,” J. Phys. Chem. |
| | B 108 (2004) 9656. |
| [15] | S. Tepavcevic, Y. Choi & L. Hanley, “Growth of novel |
| | polythiophene and polyphenyl films via surface |
| | polymerization by ion-assisted deposition,” Langmuir 20 |
| | (2004) 8754. |
| [16] | Y. Choi, S. Tepavcevic, Z. Xu & L. Hanley, “Optical and |
| | chemical properties of polythiophene films produced via |
| | surface polymerization by ion-assisted deposition,” Chem. |
| | Mater. 16 (2004) 1924. |
| [17] | Y. Choi, S. Tepavcevic & L. Hanley, “Combinatorial |
| | strategies for thin organic films - Polythiophene via surface |
| | polymerization by ion-assisted deposition,” Mater. Res. |
| | Soc. Symp. Proc. 804 (2004) JJ5.3.1. |
| [18] | S. Tepavcevic, A. T. Wroble, M. Bissen, D. J. Wallace, Y. |
| | Choi & L. Hanley, “Photoemission studies of polythiophene |
| | and polyphenyl films produced via surface polymerization |
| | by ion~assisted deposition,” J. Phys. Chem. B 109 (2005) 7134. |
| [19] | Y. Choi, A. Zachary, S. Tepavcevic, C. Wu & L. Hanley, |
| | “Polyatomicity and kinetic energy effects on surface |
| | polymerization by ion-assisted deposition,” Inter. J. Mass |
| | Spectrom. 241 (2005) 139 |
| [20] | C. A. Crot, C. Wu, M. L. Schlossman, T. P. Trainor, P J. Eng |
| | & L. Hanley, “Determining the conformation of an |
| | adsorbed Br-PEG-peptide by long period x-ray standing |
| | wave fluorescence,” Langmuir 21 (2005) 7899. |
| [21] | S. Tepavcevic & L. Hanley, “Morphology of polythiophene |
| | and polyphenyl films produced via surface polymerization |
| | by ion-assisted deposition,” J. Phys. Chem. A 110 (2006) 1618. |
| [22] | D. Asunskis & L. Hanley, “Valence-band and core-level x- |
| | ray photoelectron spectroscopy of lead sulfide QD-polymer |
| | composites,” in preparation. |
| [23] | E. J. Moniz and M. A. Kenderdine. “Meeting energy |
| | challenges: Technology and policy.” Phys. Today 55 (2002) 40-46. |
| [24] | S. Shaheen, D. S. Ginley and G. E. Jabbour. “Organic- |
| | Based Photovoltaics Special Issue.” MRC Bulletin 30 (2005). |
| [25] | M. Granstrom, M. G. Harrison and R. H. Friend (1999). |
| | Electro-optical polythiophene devices. Handbook of Oligo- |
| | and Polythiophenes. D. Fichou. Weinheim, Wiley-VCH: 405-458. |
| [26] | C. J. Brabec and N. S. Sariciftci (2000). Conjugated |
| | polymer-based plastic solar cells. Semiconducting |
| | Polymers. G. Hadziioannou and P. F. van Hutten. |
| | Weinheim, Wiley-VCH: 515-560. |
| [27] | H. Cohen. “Chemically resolved electrical measurements |
| | using x-ray photoelectron spectroscopy.” Appl. Phys. Lett. |
| | 85 (2004) 1271-1273. |
| [28] | A. J. Heeger. “Semiconducting and metallic polymers: The |
| | fourth generation of polymeric materials.” J. Phys. Chem. B |
| | 105 (2001) 8475-8491. |
| [29] | E. Kymakis and G. A. J. Amaratunga. “Single-wall carbon |
| | nanotube/conjugated polymer photovoltaic devices.” Appl. |
| | Phys. Lett. 80 (2002) 112-114. |
| [30] | S. Luzzati, M. Basso, M. Catellani, C. J. Brabec, D. |
| | Gebeyehu and N. S. Sariciftci. “Photo-induced electron |
| | transfer from a dithieno thiophene-based polymer to TiO₂.” |
| | Thin Solid Films 403-404 (2002) 52-56. |
| [31] | W. U. Huynh, J. J. Dittmer and A. P. Alivisatos. “Hyrid |
| | nanorod-polymer solar cells.” Science 295 (2002) 2425-2427. |
| [32] | A. Luque and S. Hegedus, Handbook of Photovoltaic |
| | Science and Engineering, Wiley (Chichester, 2003) |
| [33] | P. Peumans, A. Yakimov and S. R. Forrest. “Small |
| | molecular weight organic thin-film photodetectors and solar |
| | cells.” J. Appl. Phys. 93 (2003) 3693-3722. |
| [34] | G. Ertas, U. K. Demirok, A. Atalar and S. Suzer. “X-ray |
| | photoelectron spectroscopy for resistance-capacitance |
| | measurements of surface structures.” Appl. Phys. Lett. 86 |
| | (2005) 183110. |
| [35] | F. W. Wise. “Lead salt quantum dots: The limit of strong |
| | quantum confinement.” Acc. Chem. Res. 33 (2000) 773-780. |
| [36] | R. J. Ellingson, M. C. Beard, J. C. Johnson, P. Yu, O. I. |
| | Micic, A. J. Nozik, A. Shabaev and A. L. Efros. “Highly |
| | efficient multiple excition generation in colloidal PbSe and |
| | PbS quantum dots.” Nano Lett. 5 (2005) 865-871. |
| [37] | R. D. Schaller, M. A. Petruska and V. I. Klimov. “Effect of |
| | electronic structure on carrier multiplication efficiency: |
| | Comparative study of PbSe and CdSe nanocrystals.” Appl. |
| | Phys. Lett. 87 (2005) 253102. |
| [38] | P. Guyot-Sionnest. “Quantum dots: A new quantum state?” |
| | Nat. Mater. 4 (2005) 653-654. |
| [39] | A. A. R. Watt, D. Blake, J. H. Warner, E. A. Thomsen, E. |
| | L. Tavenner, H. Rubinsztein-Dunlop and P. Meredith. |
| | “Lead sulfide nanocrystal: conducting polymer solar cells.” |
| | J. Phys. D: Appl. Phys. 38 (2005) 2006-2012. |
| [40] | D. Qi, M. Fischbein, M. Drndic and S. Selmic. “Efficient |
| | polymer-nanocrystal quantum dot photodetectors.” Appl. |
| | Phys. Lett. 86 (2005) 093103. |
| [41] | E. Karabudak, U. K. Demirok and S. Suzer. “XPS analysis |
| | with pulsed voltage stimuli.” Surf. Sci. 600 (2006) L12-L14. |
| [42] | M. Hillenkamp, G. di Domenicantonio and C. Felix. |
| | “Monodispersed metal clusters in solid matrices: A new |
| | experimental setup.” Rev. Sci. Instrum. 77 (2006) 025104. |
| [43] | D. Cui, J. Xu, T. Zhu, G. Paradee, S. Ashok and M. |
| | Gerhold. “Harvest of near infrared light in PbSe |
| | nanocrystal-polymer hybrid photovoltaic cells.” Appl. Phys. |
| | Lett. 88 (2006) 183111. |
| [44] | C. Binns, K. N. Trohidou, et al. “The behaviour of |
| | nanostructured magnetic materials produced by depositing |
| | gas-phase nanoparticles.” J. Phys. D: Appl. Phys. 38 (2005) |
| | R357-379. |
| [45] | S. Lee, C. Fan, T. Wu and S. L. Anderson. “Cluster size |
| | effects on CO oxidation activity, adsorbate affinity, and |
| | temporal behavior of model Auₙ/TiO₂ catalysts.” J. Chem. |
| | Phys. 123 (2005) 124710. |
| [46] | X. Tong, L. Benz, S. Chrétien, P. Kemper, A. Kolmakov, H. |
| | Metiu, M. T. Bowers and S. K. Buratto. “Pinning mass- |
| | selected Agₙ clusters on the TiO₂(110)-1 × 1 surface via |
| | deposition at high kinetic energy.” J. Chem. Phys. 123 |
| | (2005) 204701. |
| [47] | Y.-C. Liao and J. T. Roberts. “Self-assembly of organic |
| | monolayers on aerosolized silicon nanoparticles.” J. Amer. |
| | Chem. Soc. 128 (2006) 9061-9065. |
| [48] | V. Abdelsayed, Y. Ibrahim, M. S. El-Shall and S. Deevi. |
| | “Polymerization of butadiene on nanoparticles' surfaces and |
| | formation of metal/polymer nanocomposites.” Appl. Surf. |
| | Sci. 252 (2006) 3774-3782. |
| [49] | B. Zhang, J. He and T. M. Tritt. “Size-selective high-yield |
| | growth of lead telluride (PbTe) nanocrystals using a |
| | chemical vapor deposition technique.” Appl. Phys. Lett. 88 |
| | (2006) 043119. |
| [50] | K. K. Nanda, F. E. Kruis, H. Fissan and M. Acet. “Band- |
| | gap tuning of PbS nanoparticles by in-flight sintering of size |
| | classified aerosols.” J. Appl. Phys. 91 (2002) 2315-2321. |
| [51] | H. Nasu, H. Yamada, J. Matsuoka and K. Kamiya. |
| | “Preparation of PbS microcrystal-doped SiO₂ glass thin |
| | films by the RF-sputtering method.” J. Non-Cryst. Sol. 183 |
| | (1995) 290-296. |
| [52] | R. Espiau de Lamaëstre, H. Bernas, D. Pacifici, G. Franzó |
| | and F. Priolo. “Evidence for a “dark exciton” state of PbS |
| | nanocrystals in a silicate glass.” Appl. Phys. Lett. 88 (2006) |
| | 181115. |
| [53] | W. Salaneck, M. Lögdlund, M. Fahlman, G. Greczynski and |
| | T. Kugler. “The electronic structure of polymer-metal |
| | interfaces studied by ultraviolet photoelectron |
| | spectroscopy.” Mater. Sci. Engin. Rep. 34 (2001) 121-146. |
| [54] | G. Koller, R. Blyth, S. Sardar, F. Netzer and G. Ramsey. |
| | “Band alignment at the organic-inorganic interface.” Appl. |
| | Phys. Lett. 76 (2000) 927-929. |
| [55] | Yamada and N. Toyoda. “Current research and development |
| | topics on gas cluster ion-beam processes.” J. Vac. Sci. |
| | Technol. A 23 (2005) 1090-1099 |
| [56] | A. Biswas, H. Eilers, F. J. Hidden, O. C. Aktas and C. V. S. |
| | Kiran. “Large broadband visible to infrared plasmonic |
| | absorption from Ag nanoparticles with a fractal structure |
| | embedded in a Teflon AF ® matrix.” Appl. Phys. Lett. 88 |
| | (2006) 013103. |
| [57] | A. Biswas et al., “Vapor phase deposition of nanostructured |
| | polymer-metal composites for advanced technology |
| | applications”, Vac. Technol. Coating 7 (2006) 54-59 (Issue |
| | 4, April). |
| [58] | Shaheen, S.; Ginley, D. S.; Jabbour, G. E., MRS Bull. 2005, |
| | 30: 1, accompanying articles in issue and references therein. |
| [59] | Wise, F. W., Acc. Chem. Res. 2000, 33, 773. |
| [60] | Joo, J.; Na, H. B.; Yu, T.; Yu, J. H.; Kim, Y. W.; Wu, F.; |
| | Zhang, J. Z.; Heong, T., J. Am. Chem. Soc. 2003, 125, 11100. |
| [61] | Watt, A. A.; Meredith, P.; Riches, J. D.; Atkinson, S.; |
| | Rubinsztein-Dunlop, H., Curr. Appl. Phys. 2004, 4, 320. |
| [62] | Zhang, S.; Cyr, P.; McDonald, S. A.; Konstantatos, G.; |
| | Sargent, E. H., Appl. Phys. Lett. 2005, 87, 233101. |
| [63] | Cademartiri, L.; Montanari, E.; Calestani, G.; Migliori, A.; |
| | Guagliardi, A.; Ozin, G. A., J. Am. Chem. Soc. 2006, 128, 10337. |
| [64] | Kim, H. S.; Lee, M. H.; Jeong, N. C.; Lee, S. M.; Rhee, B. |
| | K.; Yoon, K. B., J. Am. Chem. Soc. 2006, 128, 15070. |
| [65] | Cademartiri, L.; Freymann, G. v.; Arsenault, A. C.; |
| | Bertolotti, J.; Wiersma, D. S.; Kitaev, V.; Ozin, G. A., |
| | Small 2005, 1, 1184. |
| [66] | Hanley, L.; Sinnott, S. B., Surf. Sci. 2002, 500, 500. |
| [67] | Nanda, K. K.; Kruis, F. E.; Fissan, H.; Acet, M. J., Appl. |
| | Phys. 2002, 91, 2315. |
| [68] | Yamada, I.; Toyoda, N., J. Vac. Sci. Technol. A 2005, 23, 1090. |
| [69] | Liao, Y.-C.; Roberts, J. T., J. Amer. Chem. Soc. 2006, 128, 9061. |
| [70] | Partridge, J. G.; Mackenzie, D. M. A.; Reichel, R.; Brown, |
| | S. A., Microelec. Engin. 2006, 83, 1460. |
| [71] | Cui, T.; Cui, F.; Zhang, J.; Wang, J.; Huang, J.; Lü, C.; |
| | Chen, Z.; Yang, B., J. Am. Chem. Soc. 2006, 128, 6298. |
| [72] | Heine, J. R.; Rodriguez-Viejo, J.; Bawendi, M. G.; Jensen, |
| | K. F., J. Cryst. Growth 1998, 195, 564. |
| [73] | Wang, J.-Y.; Chen, W.; Liu, A.-H.; Lu, G.; Zhang, G.; |
| | Zhang, J.-H.; Yang, B., J. Am. Chem. Soc. 2002, 124, 13358. |
| [74] | Urban, J. J.; Talapin, D. V.; Shevchenko, E. V.; Murray, C. |
| | B., J. Am. Chem. Soc. 2006, 128, 3248. |
| [75] | Salzman, R. F.; Xue, J.; Alexander, B. P.; Thompson, M. |
| | E.; Forrest, S. R., Organic Electronics 2005, 6, 242. |
| [76] | Torre, G. d. l.; Vázquez, P.; Agulló-López, F.; Torres, T., |
| | Chem. Rev. 2004, 104, 3723. |
| [77] | Haberland, H.; Karrais, M.; Mall, M.; Thurner, Y., |
| | J. Vac. Sci. Technol A 1992, 10, 3266. |
| [78] | Mihailescu, G. H.; Borodi, G. H.; Candea, R. M., J. Mater. |
| | Sci. Lett. 1994, 13, 1675. |
| [79] | Choi, Y. S.; Zachary, A.; Tepavcevic, S.; Wu, C.; Hanley, |
| | L., Inter. J. Mass Spectrom. Ion Proces. 2005, 241, 139. |
| [80] | Nozik, A., Annu. Rev. Phys. Chem. 2001, 52, 193. |
| [81] | Ellingson, R. J.; Beard, M. C.; Johnson, J. C.; Yu, P.; Micic, |
| | O. I.; Nozik, A. J.; Shabaev, A.; Efros, A. L., Nano Lett. |
| | 2005, 5, 865. |
| [82] | Schaller, R. D.; Sykora, M.; Pietryga, J. M.; Klimov, V. I., |
| | Nano Lett. 2006, 6, 424. |
| [83] | Patontep, S.; S. J. Carroll; C. Xirouchaki; M. Streun; |
| | R. E. Palmer, Rev. Sci. Instrum. 2005, 76, 0451103-1. |
| [84] | Asunskis, D. J.; Hanley, L., submitted. |
| [85] | Edvards, L.; Gouterman, M., J. Mol. Spectrosc. 1970, 33, 292. |
| [86] | Gunaratne, T.; Kennedy, V. O.; Kenney, M. E.; Rodgers, |
| | M. A. J., J. Phys. Chem. A 2004, 108, 2576. |
| [87] | Zhu, R.; Chen, Y.; Zhou, J.; Li, B.; Liu, W.; Qian, S.; |
| | Hanack, M.; Araki, Y.; Ito, O., Chem. Phys. Lett. 2004, 398, 308. |
| [88] | F. W. Wise, Acc. Chem. Res. 2000, 33, 773. |
| [89] | M. A. Hines, G. D. Scholes, Adv. Mater. 2003, 15, 1844. |
| [90] | A. A. Watt, P. Meredith, J. D. Riches, S. Atkinson, H. |
| | Rubinsztein-Dunlop, Curr. Appl. Phys. 2004, 4, 320. |
| [91] | S. A. McDonald, G. Konstantatos, S. Zhang, P. W. Cyr, |
| | E. J. D. Klem, L. Levina, E. H. Sargent, Nat. Mater. 2005, 4, 138. |
| [92] | S. Zhang, P. W. Cyr, S. A. McDonald, G. Konstantatos, E. H. |
| | Sargent, Appl. Phys. Lett. 2005, 87, 233101. |
| [93] | D. Qi, M. Fischbein, M. Drndic, S. Selmic, Appl. Phys. |
| | Lett. 2005, 86, 093103. |
| [94] | A. Watt, E. Thomsen, P. Meredith, H. Rubinsztein-Dunlop, |
| | Chem. Comm. 2004, 2334. |
| [95] | A. Nozik, Inorg. Chem. 2005, 44, 6893. |
| [96] | H. Haberland, M. Karrais, M. Mall, Y. Thurner, |
| | J. Vac. Sci. Technol. A 1992, 10, 3266. |
| [97] | A. Lobo, T. Moller, M. Nagel, H. Borchert, S. G. Hickey, H. |
| | Weller, J. Phys. Chem. B. 2005, 89, 17422. |
| [98] | Y. Choi, S. Tepavcevic, Z. Xu, L. Hanley, Chem. Mater. |
| | 2004, 16, 1924 and references therein. |

The foregoing description and the accompanying drawings are illustrative of the present invention. Still other variations in arrangements of the parts and materials are possible without departing from the spirit and scope of this invention.

1. The method of claim 3 wherein the conducting polymer film is produced by co-depositing surface polymerizing organic monomers, oligomers or both monomers and oligomers with gaseous lead salt clusters on said substrate to form a conducting polymer matrix embedded with said lead salt clusters.

2. The method of claim 3 wherein the lead salt clusters and conducting polymer film are simultaneously deposited on the substrate so as to embed the lead salt clusters in the conducting polymer film.

3. A method of producing a nanocomposite film on a substrate by gaseous deposition comprising co-depositing gaseous lead salt clusters in a conducting polymer film on the substrate.

4. (canceled)

5. The method of claim 3 wherein the conducting polymer film is prepared by co-depositing an organic ion and a neutral oligomer on the substrate.

6. The method of claim 5 wherein the organic ion is selected from the group consisting of H⁺, H₂S⁺, SO₃⁺, C₂Hₓ⁺, C₄H₄S⁺, C₆H₆⁺, C₆H₇N⁺, C₅H₅N⁺, C₄H₄O⁺, and other small organic ion species as well as derivatives thereof, and mixtures thereof.

7. The method of claim 5 wherein the neutral oligomer comprises monomer units selected from the group consisting of terthiophene, sexithiophene, ethylenedioxythiophene, terphenyl, quaterphenyl, sexiphenyl, poly(phenylene vinylenes), porphyrins, phthalocyanines, pentacene, diphenyl perylene, derivatives thereof, and mixtures thereof.

8. The method of claim 5 wherein the organic ion comprises a thiophene ion and the neutral oligomer comprises an oligomer of thiophene.

9. (canceled)

10. (canceled)

11. An optical device comprising a lens or a coating on a lens formed of a nanocomposite material, said nanocomposite material comprising a conducting polymer film and a plurality of lead salt clusters dispersed in the conducting polymer film.

12. The optical device of claim 11 wherein the lead salt clusters are arranged in a three-dimensional matrix.

13. (canceled)

14. A photovoltaic cell including a nanocomposite film prepared by the method of claim 3.

15. A method of producing a nanocomposite film by trapping gaseously deposited lead salt clusters in a gaseously deposited conducting polymer.

16. The method of claim 15 wherein the lead salt clusters are trapped in the conducting polymer by simultaneously gaseously depositing the lead salt clusters and the conducting polymer.

17. The method of claim 3 wherein the lead salt clusters are formed in a vacuum environment.

18. The method of any claim 3 wherein the lead salt clusters are selected from the group consisting of lead sulfides, lead selenide, lead telluride and mixtures thereof.

19. (canceled)

20. An article of manufacture including a nanocomposite film prepared by the method claim 3.

21. The optical device of claim 11 wherein the optical device attenuates pulsed laser radiation of wavelengths ranging from about 400 to about 900 nm incident on the device surface such that the radiation transmitted by the device does not exceed a laser power density of about 15 microJoules/cm2 per pulse.

22. A photovoltaic cell including a nanocomposite film prepared by the method of claim 3, deposited onto a transparent conductive electrode.

23. The photovoltaic cell according to claim 22 wherein the transparent conductive electrode comprises indium tin oxide coated glass.

24. The photovoltaic cell according to claim 23 wherein the transparent conductive electrode is coated with an aluminum overlayer.

25. The photovoltaic cell according to claim 24 wherein the aluminum overlayer has a thickness of approximately 10 nm.
